(19) United States
(12) Patent Application Publication
(10) Pub. No.: US 2025/0081553 A1
(43) Pub. Date: Mar. 6, 2025

(54) POWER SEMICONDUCTOR DEVICE

(71) Applicant: University of Electronic Science and Technology of China, Chengdu (CN)

(72) Inventors: Ming QIAO, Chengdu (CN); Jue LI, Chengdu (CN); Zesheng SHI, Chengdu (CN); Daoming SHEN, Chengdu (CN); Bo ZHANG, Chengdu (CN)

(73) Assignee: University of Electronic Science and Technology of China, Chengdu (CN)

(21) Appl. No.: 18/388,870

(22) Filed: Nov. 13, 2023

(30) Foreign Application Priority Data
Aug. 28, 2023 (CN) 2023110949394

(51) Int. Cl. H01L 29/06

(52) U.S. Cl. CPC H10D 62/127; H10D 62/115

(57) ABSTRACT

A power semiconductor device, including a cell region, a transition region, and a terminal region. The transition region is located between the cell region and the terminal region of the device. A first conduction type substrate, a first conduction type epitaxial layer located above the first conduction type substrate, and a first conduction type buffer layer located in the first conduction type epitaxial layer are jointly arranged at the bottoms of the cell region, the transition region, and the terminal region of the device. In a high-current application, since the cell region occupies the largest area of a chip, in a case that breakdown can occur in the cell region and the current can be discharged through the cell region. On the basis of ensuring the BV of the terminal region, a silicon layer step is formed by elevating the position of a top structure of the terminal region.

### CROSS REFERENCE TO RELATED APPLICATION

This application is based on and claims foreign priority to Chinese patent application 202311094939.4 filed on Aug. 28, 2023, the entire content of which is incorporated herein by reference.

### TECHNICAL FIELD

The present disclosure belongs to the technical field of semiconductors, and relates to a super-junction power semiconductor device.

### BACKGROUND

A power MOS device is one of main devices for power processing and conversion, and has the advantages of high input impedance, easy driving and the like; therefore, the power MOS device is widely applied in the fields of automobile electrons, industrial electrons, consumer electrons and the like. The ideal power MOS device often requires a high breakdown voltage (BV) and a low specific on resistance (R_{on,sp}), so that the conduction loss can be reduced as much as possible. However, due to the limitation of a “silicon limit” relationship, R_{on,sp} and BV of the traditional MOS device have a restrictive relationship. Therefore, a super-junction device was invented in 1880s, and the introduction of the super-junction structure greatly relieves the contradiction between R_{on,sp} and BV. The super-junction device realizes charge compensation by alternating P-type and N-type regions so as to obtain a lower specific on resistance R_{on,sp} and a higher breakdown voltage BV. The super-junction device has high performance, but the terminal structure of the super-junction device is sensitive to charge imbalance and an optimization window is small. Therefore, for the design of the terminal structure, it is very important for the super-junction application to improve the BV of the terminal structure and reduce the charge imbalance sensitivity of the terminal. In the high-voltage and high-current application, breakdown occurs in a large-area active region, which is more beneficial to the application of the device, but a low-current device tends to that breakdown occurs in a larger-area non-active area. According to the present disclosure, based on a high-current application device, to transfer the breakdown position into the cell region, the structures of the transition region and the terminal region of the device are designed, so that the voltage-resistant lengths of the transition region and the terminal region are higher than that of the cell region thereby improving the breakdown characteristic, and enhancing the EAS characteristic and reliability of the device. In a case of the low-current application, the same principle can be adopted, and the design directions are different, thereby transferring the breakdown point position.

### SUMMARY

The present disclosure provides a power semiconductor device for voltage resistance optimization of terminal design.

To achieve the aforementioned objective of the present disclosure, the technical solution of the present disclosure is as follows:
a power semiconductor device includes a cell region 100, a transition region 101 and a terminal region 102, where the transition region 101 is located between the cell region 100 and the terminal region 102 of the device; the cell region 100, the transition region 101 and the terminal region 102 of the device have a common bottom structure; the bottom structure includes a drain electrode metal 17, a first conduction type substrate 1 located above the drain electrode metal, a first conduction type epitaxial layer 2 located above the first conduction type substrate 1, and a first conduction type buffer layer 3 located at an inner bottom of the first conduction type epitaxial layer 2; a direction from the first conduction type epitaxial layer 2 to the first conduction type substrate 1 is defined as a device longitudinal direction, and a direction from the cell region 100 to the terminal region 102 is defined as a device transverse direction;
in the cell region 100, first conduction type longitudinal strip-shaped regions 4 and second conduction type longitudinal strip-shaped regions 5 which are distributed alternately in a transverse direction are arranged in the first conduction type epitaxial layer 2, second conduction type body regions 9 are arranged at the tops of the first conduction type longitudinal strip-shaped regions 4 and the second conduction type longitudinal strip-shaped regions 5, and first conduction type heavy doping regions 11 and second conduction type body contact regions 10 are arranged in the second conduction type body regions 9; the first conduction type heavy doping regions 11 are located on left and right sides of the second conduction type body contact regions 10; the first conduction type heavy doping regions 11 and the second conduction type body contact regions 10 are connected to a source electrode metal 16; gateoxide layers 12 are arranged above the second conduction type body regions 9; gate polysilicon 13 is arranged above the gateoxide layers 12, and dielectric layers 14 and the source electrode metal 16 are arranged above the gate polysilicon 13;
in the transition region 101, first conduction type longitudinal strip-shaped regions 4 and second conduction type longitudinal strip-shaped regions 5 which are distributed alternately in the transverse direction are arranged in the first conduction type epitaxial layer 2, a second conduction type isolating body region 6 is arranged at the tops of the first conduction type longitudinal strip-shaped regions 4 and the second conduction type longitudinal strip-shaped regions 5, and the second conduction type longitudinal strip-shaped regions 5 and the first conduction type longitudinal strip-shaped regions 4 are connected to the second conduction type isolating body region 6; a dielectric layer 14 is arranged above the second conduction type isolating body region 6;
the terminal region 102 includes first conduction type longitudinal strip-shaped regions 4 and second conduction type longitudinal strip-shaped regions 5 which are alternately distributed in the transverse direction, a second conduction type transverse strip-shaped region 7 is arranged at the tops of the first conduction type longitudinal strip-shaped regions 4 and the second conduction type longitudinal strip-shaped regions 5, a left-side boundary of the second conduction type transverse strip-shaped region 7 is connected to the second conduction type isolating body region 6 in the transition region, a lower boundary of the second conduction type transverse strip-shaped region 7 is not lower than a lower boundary of the second conduction type isolating body region 6, and the lower boundary of the second conduction type isolating body region 6 is not lower than lower boundaries of the second conduction type body regions 9;
the lower boundary of the second conduction type transverse strip-shaped region 7 is connected to a plurality of the first conduction type longitudinal strip-shaped regions 4 and the second conduction type longitudinal strip-shaped regions 5; a first conduction type transverse strip-shaped region 8 is arranged above the second conduction type transverse strip-shaped region 7, and an upper boundary of the first conduction type transverse strip-shaped region 8 is higher than a silicon-oxide interface at the junction of the second conduction type isolating body region 6 and the dielectric layer 14 of the transition region 101 to form a silicon layer step; and a dielectric layer 14 is arranged above the first conduction type transverse strip-shaped region 8, a drain electrode polysilicon field plate 15 is arranged in the dielectric layer 14 and located at the rightmost end of the device, and a first conduction type heavy doping region 11 is arranged below the drain electrode polysilicon field plate 15 and is in short-circuit connection with the drain electrode polysilicon field plate 15.

As a preferred manner, the lower boundary of the second conduction type transverse strip-shaped region 7 is flush with the lower boundary of the second conduction type isolating body region 6, and the lower boundary of the second conduction type isolating body region 6 is flush with the lower boundaries of the second conduction type body regions 9.

As a preferred manner, the lower boundary of the second conduction type transverse strip-shaped region 7 in the terminal region 102 is higher than the lower boundary of the second conduction type isolating body region 6.

As a preferred manner, the lower boundary of the second conduction type isolating body region 6 in the transition region 101 is higher than the lower boundaries of the second conduction type body regions 9 in the cell region 100, and the lower boundary of the second conduction type transverse strip-shaped region 7 in the terminal region 102 is flush with the lower boundary of the second conduction type isolating body region 6.

As a preferred manner, the lower boundary of the second conduction type isolating body region 6 in the transition region 101 is higher than the lower boundaries of the second conduction type body regions 9 in the cell region 100, and the lower boundary of the second conduction type transverse strip-shaped region 7 in the terminal region 102 is higher than the lower boundary of the isolating body region 6.

As a preferred manner, the lower boundary of the second conduction type isolating body region 6 in the transition region 101 is lifted from left to right to be in flush with the lower boundary of the second conduction type transverse strip-shaped region 7 in the terminal region 102, and a left lower boundary of the second conduction type isolating body region 6 is flush with the lower boundaries of the second conduction type body regions 9.

As a preferred manner, a step of the first conduction type transverse strip-shaped region 8 and the dielectric layer 14 above at the junction of the transition region 101 and the terminal region 102 is of a right-angle or slope structure.

As a preferred manner, the first conduction type transverse strip-shaped region 8 and the second conduction type transverse strip-shaped region 7 in the terminal region 102 are lifted from left to right in a stepped shape and in a segmented manner.

As a preferred manner, an upper surface and a lower surface of the second conduction type transverse strip-shaped region 7 in the terminal region 102 are lifted from left to right in a slope shape from a right boundary of the second conduction type isolating body region 6, and the thickness of the second conduction type transverse strip-shaped region 7 is unchanged.

As a preferred manner, a lower surface of the second conduction type transverse strip-shaped region 7 in the terminal region 102 is lifted from left to right in a slope shape from a right boundary of the second conduction type isolating body region 6, and an upper surface of the second conduction type transverse strip-shaped region 7 is kept horizontal.

As a preferred manner, the second conduction type transverse strip-shaped region 7 in the terminal region 102 is divided into a left-side part and a right-side part with the same thickness, the left-side part is lifted in a slope shape from a right boundary of the second conduction type isolating body region 6, and the right-side part is kept horizontal.

As a preferred manner, a second conduction type thin layer region 18 is arranged at the top of the first conduction type transverse strip-shaped region 8.

As a preferred manner, a plurality of the first conduction type longitudinal strip-shaped regions 4 and the second conduction type longitudinal strip-shaped regions 5 which are not connected to the second conduction type transverse strip-shaped region 7 are arranged below the right side of the second conduction type transverse strip-shaped region 7.

As a preferred manner, in the cell region 100, second conduction type body regions 9 are arranged at the top of the first conduction type epitaxial layer 3; and in the second conduction type body regions 9, trenches extending to the first conduction type longitudinal strip-shaped regions 4 below are formed, the trenches are filled with gateoxide layers 12 and gate electrode polysilicon 13, first conduction type heavy doping regions 11 are arranged on two sides of the trenches, the first conduction type heavy doping regions 11 and second conduction type body contact regions 10 are connected to a source electrode metal 16, and a second conduction type implantation region 19 is arranged in the first conduction type epitaxial layer 2 and located at the bottoms of the trenches

As a preferred manner, in the cell region 100, a stepped oxide layer with a thick middle part and two thin sides is arranged above the second conduction type body regions 9, and thin oxide layers above channel regions on two sides are gateoxide layers 12.

As a preferred manner, in the cell region 100, each of the first conduction type longitudinal strip-shaped regions 4 has a concentration the same as or different from that of the first conduction type epitaxial layer 2, and/or a first conduction type JFET implantation region is arranged at the top of each of the first conduction type longitudinal strip-shaped regions 4.

As a preferred manner, in the transition region 101, a first conduction type heavy doping region is added in the second conduction type isolating body region 6 to serve as a channel structure.

As a preferred manner, the first conduction type longitudinal strip-shaped regions 4, the second conduction type longitudinal strip-shaped regions 5, the first conduction type transverse strip-shaped region 8, the second conduction type isolating body region 6 and the second conduction type transverse strip-shaped region 7 are obtained by a method of multi-epitaxy and ion implantation; or/and
the silicon layer step between the transition region 101 and the terminal region 102 is obtained through a process of etching after epitaxy or local epitaxy.

As a preferred manner, the structure includes an N-type power semiconductor device and a terminal structure thereof, and a P-type power semiconductor device and a terminal structure thereof; for the terminal structure of the N-type power semiconductor device, the first conduction type is an N type, and the second conduction type is a P type; and for the terminal structure of the P-type semiconductor device, the first conduction type is the P type, and the second conduction type is the N type.

The inventive principle of the present disclosure is: a stepped silicon layer is arranged at the device terminal; in off state of the device, by lifting the position of the top structure of the terminal region, the length of the longitudinal P/N strip of the terminal is increased, the longitudinal voltage-resistant length of the terminal region is increased, and the BV difference value between the cell and terminal regions is reduced; and meanwhile, by adding the transverse P/N strip at the top for assisting in depletion, the voltage-resistant level of the terminal is further increased, so that the breakdown position of the device is transferred to the cell region.

The present disclosure has the following beneficial effects: according to the present disclosure, on the basis that the super junction serves as a switching device to optimize the breakdown voltage and the specific on resistance, the length of the longitudinal P/N strip of the terminal region participating in the depletion in the off state is increased by lifting the position of the silicon layer at the top of the terminal region, so that the longitudinal voltage-resistant length of the terminal region is increased, the BV of the terminal region is higher than that of the cell region, the position of the breakdown point is transferred to the cell region, all current is discharged through the large-area cell region, the problems of sensitive terminal charge balance and easy breakdown at the boundaries of the transition region and the terminal region are solved, and the EAS performance and robustness of the device are improved.

### BRIEF DESCRIPTION OF DRAWINGS

FIG. 1 is a schematic diagram of an original structure of a power semiconductor device in the prior art;

FIG. 2 is a structural schematic diagram of a power semiconductor device according to Embodiment 1 of the present disclosure;

FIG. 3 is a structural schematic diagram of a power semiconductor device according to Embodiment 2 of the present disclosure;

FIG. 4 is a structural schematic diagram of a power semiconductor device according to Embodiment 3 of the present disclosure;

FIG. 5 is a simulation comparison schematic diagram of Embodiment 1 and Embodiment 3 of the present disclosure and an existing original structure;

FIG. 6 is a structural schematic diagram of a power semiconductor device according to Embodiment 4 of the present disclosure;

FIG. 7 is a structural schematic diagram of a power semiconductor device according to Embodiment 5 of the present disclosure;

FIG. 8 is a structural schematic diagram of a power semiconductor device according to Embodiment 6 of the present disclosure;

FIG. 9 is a structural schematic diagram of a power semiconductor device according to Embodiment 7 of the present disclosure;

FIG. 10 is a structural schematic diagram of a power semiconductor device according to Embodiment 8 of the present disclosure;

FIG. 11 is a structural schematic diagram of a power semiconductor device according to Embodiment 9 of the present disclosure;

FIG. 12 is a structural schematic diagram of a power semiconductor device according to Embodiment 10 of the present disclosure;

FIG. 13 is a structural schematic diagram of a power semiconductor device according to Embodiment 11 of the present disclosure;

FIG. 14 is a structural schematic diagram of a power semiconductor device according to Embodiment 12 of the present disclosure;

FIG. 15 is a structural schematic diagram of a power semiconductor device according to Embodiment 13 of the present disclosure;

FIG. 16 is a structural schematic diagram of a power semiconductor device according to Embodiment 14 of the present disclosure;

100: cell region; 101: transition region; 102: terminal region; 1: first conduction type substrate; 2: first conduction type epitaxial layer; 3: first conduction type buffer layer; 4: first conduction type longitudinal strip-shaped region; 5: second conduction type longitudinal strip-shaped region; 6: second conduction type isolating body region; 7: second conduction type transverse strip-shaped region; 8: first conduction type transverse strip-shaped region; 9: second conduction type body region; 10: second conduction type body contact region: 11: first conduction type heavy doping region; 12: gateoxide layer; 13: gate polysilicon; 14: dielectric layer; 15: drain electrode polysilicon field plate; 16: source electrode metal; 17: drain electrode metal; 18: second conduction type thin layer region; 19: second conduction type implantation region.

### DETAILED DESCRIPTION OF THE EMBODIMENTS

The implementation manners of the present disclosure are described below by the specific embodiments. Those skilled in the art may easily understand other advantages and effects of the present disclosure by the contents disclosed by the specification. The present disclosure can be implemented or applied through other different specific implementation manners. Various modifications or changes can be made to various details in the specification based on different viewpoints and applications without departing from the spirit of the present disclosure.

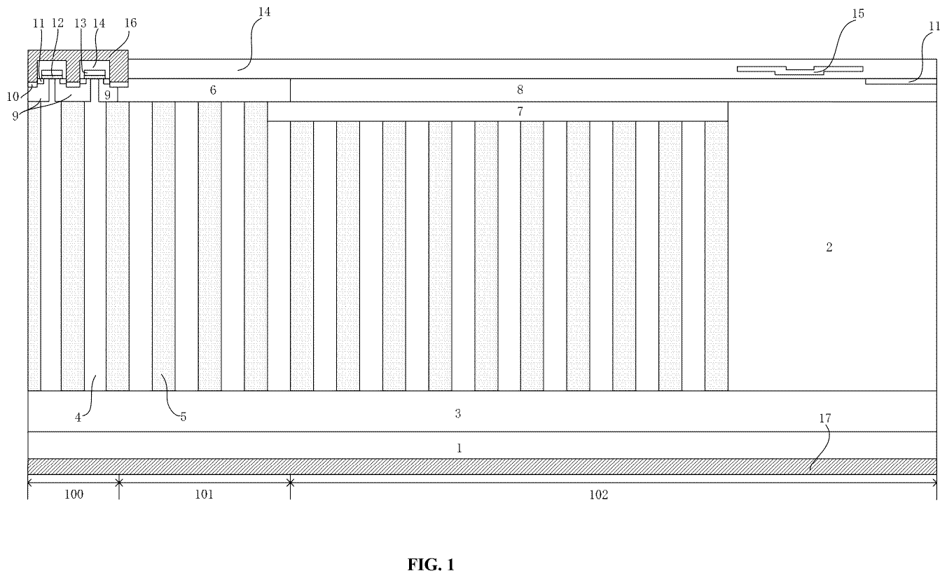

As shown in FIG. 1 which is a schematic diagram of an original structure of an existing power semiconductor device, the terminal structure adopts auxiliary depletion of the top transverse first/second conduction type strip in the off state, the voltage-resistant level of the terminal region can be flexibly adjusted based on the characteristics of length and doping adjustability of the second conduction type transverse strip-shaped region, and the second conduction type transverse strip-shaped region of the terminal region connects longitudinal strips together, thereby providing a flow path for holes and optimizing the dynamic characteristic of the device. However, based on the structure shown in FIG. 1, the longitudinal voltage-resistant lengths of the cell and transition regions are not matched with the longitudinal voltage-resistant length of the terminal region, and the longitudinal voltage-resistant length of the terminal region is less than those of the cell and transition regions, so that the device is easy to break down at the boundary of the transition region in the off state, and the charge balance and BV optimization of the terminal structure are limited; and meanwhile, in a case that the breakdown point is located at the transition region, the transition region occupies a small proportion in the area of the device, so it is not conducive to improving the robustness of the device.

### Embodiment 1

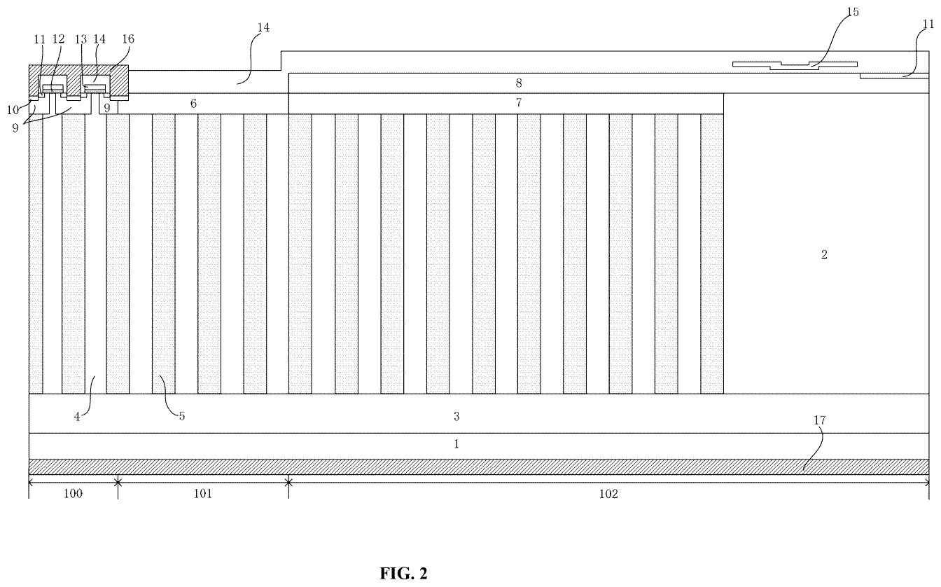

This embodiment provides an optimized structure of a power semiconductor device, as shown in FIG. 2, including a cell region 100, a transition region 101 and a terminal region 102,
where the transition region 101 is located between the cell region 100 and the terminal region 102 of the device; the cell region 100, the transition region 101 and the terminal region 102 of the device have a common bottom structure; the bottom structure includes a drain electrode metal 17, a first conduction type substrate 1 located above the drain electrode metal, a first conduction type epitaxial layer 2 located above the first conduction type substrate 1, and a first conduction type buffer layer 3 located at an inner bottom of the first conduction type epitaxial layer 2; a direction from the first conduction type epitaxial layer 2 to the first conduction type substrate 1 is defined as a device longitudinal direction, and a direction from the cell region 100 to the terminal region 102 is defined as a device transverse direction;
in the cell region 100, first conduction type longitudinal strip-shaped regions 4 and second conduction type longitudinal strip-shaped regions 5 which are distributed alternately in a transverse direction are arranged in the first conduction type epitaxial layer 2, second conduction type body regions 9 are arranged at the tops of the first conduction type longitudinal strip-shaped regions 4 and the second conduction type longitudinal strip-shaped regions 5, and first conduction type heavy doping regions 11 and second conduction type body contact regions 10 are arranged in the second conduction type body regions 9; the first conduction type heavy doping regions 11 are located on left and right sides of the second conduction type body contact regions 10; the first conduction type heavy doping regions 11 and the second conduction type body contact regions 10 are connected to a source electrode metal 16; gateoxide layers 12 are arranged above the second conduction type body regions 9; gate polysilicon 13 is arranged above the gateoxide layers 12, and dielectric layers 14 and the source electrode metal 16 are arranged above the gate polysilicon 13;
in the transition region 101, first conduction type longitudinal strip-shaped regions 4 and second conduction type longitudinal strip-shaped regions 5 which are distributed alternately in the transverse direction are arranged in the first conduction type epitaxial layer 2, a second conduction type isolating body region 6 is arranged at the tops of the first conduction type longitudinal strip-shaped regions 4 and the second conduction type longitudinal strip-shaped regions 5, and the second conduction type longitudinal strip-shaped regions 5 and the first conduction type longitudinal strip-shaped regions 4 are connected to the second conduction type isolating body region 6; a dielectric layer 14 is arranged above the second conduction type isolating body region 6;
the terminal region 102 includes first conduction type longitudinal strip-shaped regions 4 and second conduction type longitudinal strip-shaped regions 5 which are alternately distributed in the transverse direction, a second conduction type transverse strip-shaped region 7 is arranged at the tops of the first conduction type longitudinal strip-shaped regions 4 and the second conduction type longitudinal strip-shaped regions 5, a left-side boundary of the second conduction type transverse strip-shaped region 7 is connected to the second conduction type isolating body region 6 in the transition region, a lower boundary of the second conduction type transverse strip-shaped region 7 is not lower than a lower boundary of the second conduction type isolating body region 6, and the lower boundary of the second conduction type isolating body region 6 is not lower than lower boundaries of the second conduction type body regions 9;
the lower boundary of the second conduction type transverse strip-shaped region 7 is connected to a plurality of the first conduction type longitudinal strip-shaped regions 4 and the second conduction type longitudinal strip-shaped regions 5; a first conduction type transverse strip-shaped region 8 is arranged above the second conduction type transverse strip-shaped region 7, and an upper boundary of the first conduction type transverse strip-shaped region 8 is higher than a silicon-oxide interface at the junction of the second conduction type isolating body region 6 and the dielectric layer 14 of the transition region 101 to form a silicon layer step; and a dielectric layer 14 is arranged above the first conduction type transverse strip-shaped region 8, a drain electrode polysilicon field plate 15 is arranged in the dielectric layer 14 and located at the rightmost end of the device, and a first conduction type heavy doping region 11 is arranged below the drain electrode polysilicon field plate 15 and is in short-circuit connection with the drain electrode polysilicon field plate 15.

Preferably, in the cell region 100, each of the first conduction type longitudinal strip-shaped regions 4 adopts a concentration different from that of the first conduction type epitaxial layer 2, and/or a first conduction type JFET implantation region is arranged at the top of each of the first conduction type longitudinal strip-shaped regions 4.

Preferably, in the transition region 101, a first conduction type heavy doping region is added in the second conduction type isolating body region 6 to serve as a channel structure.

Preferably, the first conduction type longitudinal strip-shaped regions 4, the second conduction type longitudinal strip-shaped regions 5, the first conduction type transverse strip-shaped region 8, the second conduction type isolating body region 6 and the second conduction type transverse strip-shaped region 7 are obtained by a method of multi-epitaxy and ion implantation; or/and
the silicon layer step between the transition region 101 and the terminal region 102 is obtained through a process of etching after epitaxy or local epitaxy.

Preferably, the structure includes an N-type power semiconductor device and a terminal structure thereof, and a P-type power semiconductor device and a terminal structure thereof; for the terminal structure of the N-type power semiconductor device, the first conduction type is an N type, and the second conduction type is a P type; and for the terminal structure of the P-type semiconductor device, the first conduction type is the P type, and the second conduction type is the N type.

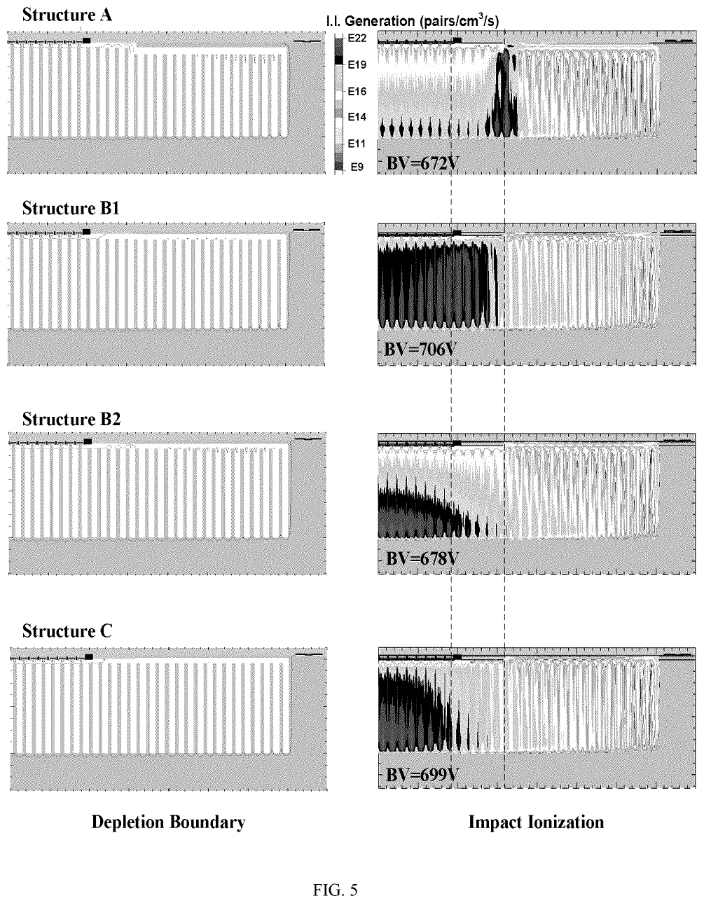

The working principle of this embodiment is: in this embodiment, a stepped silicon layer is arranged at the device terminal; in off state of the device, the length of the longitudinal P/N strip of the terminal and the longitudinal voltage-resistant length of the terminal region are increased to optimize the voltage resistance balance between the cell and terminal regions; meanwhile, by adding the transverse P/N strip at the top for assisting in depletion, the voltage-resistant level of the terminal is further increased; and as shown in FIG. 5, the structure A is an original terminal structure without the silicon layer step shown in FIG. 1, the structure B1 is a terminal structure in a case that the thickness of the first conduction type transverse strip-shaped region 8 shown in FIG. 2 is 1 μm, and the structure B2 is a terminal structure in a case that the thickness of the region 8 shown in FIG. 2 is 1.5 μm. According to the traditional structure A in FIG. 1, since the lengths of the longitudinal P/N strips in the cell region and the transition region are greater than the longitudinal length of the terminal region, voltage difference is easy to occur at the boundary of the terminal and the transition region, the device is broken down at the junction, and the concentration design window is small and the stability is insufficient; after the position of the second conduction type transverse strip-shaped region 7 and the structure above the second conduction type transverse strip-shaped region is lifted and the longitudinal voltage-resistant length of the terminal region is increased, as shown in the structure B1, the depletion at the top of the junction position of the transition region and the terminal region is optimized, and the breakdown position of the device is transferred from the terminal to the cell; with the increase of the thickness of the silicon layer step (the thickness of the second conduction type transverse strip-shaped region 8), as shown in the structure B2, the transverse P/N strip structure at the top of the device assists in depletion, so that all the impact ionization position is almost transferred into the cell region; and the optimized structure transfers the current discharge path to the large-area cell region when the device break down, so that the avalanche tolerance of the device is improved, the charge imbalance sensitivity of the terminal structure is reduced, and the reliability of the device is improved.

### Embodiment 2

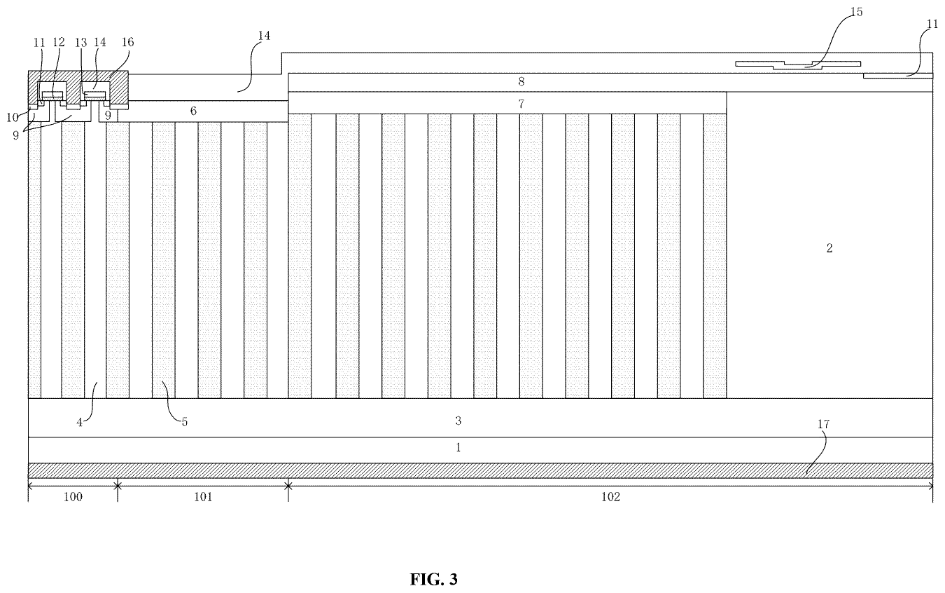

As shown in FIG. 3, the difference between this embodiment and Embodiment 1 is that: the lower boundary of the second conduction type transverse strip-shaped region 7 in the terminal region 102 is higher than the lower boundary of the second conduction type isolating body region 6. In this embodiment, the longitudinal voltage-resistant length of the terminal region is further increased; and in the reverse voltage resistance process, the terminal region can obtain a higher voltage-resistant allowance compared with the cell region, so that the breakdown position is further transferred into the cell, the off-state BV of the device is improved, and according to different voltage-resistant requirements, the offset of the region position can be adjusted.

### Embodiment 3

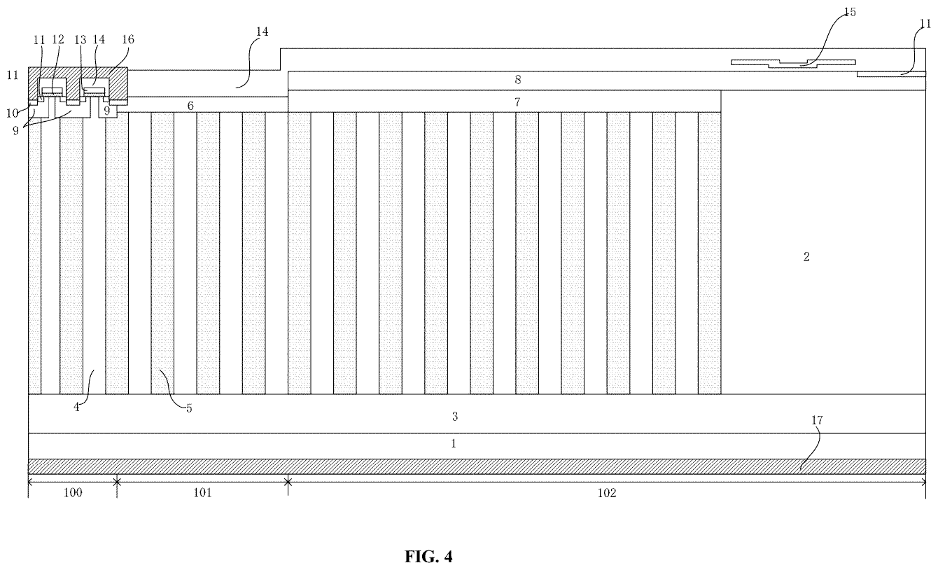

As shown in FIG. 4, the difference between this embodiment and Embodiment 1 is that: the lower boundary of the second conduction type isolating body region 6 in the transition region 101 is higher than the lower boundary of the second conduction type body region 9 in the cell region 100, and the lower boundary of second conduction type transverse strip-shaped region 7 in the terminal region 102 is flush with the lower boundary of the second conduction type isolating body region 6. In this embodiment, by increasing the longitudinal voltage-resistant length of the transition region and combining with the optimization of the voltage-resistant length of the terminal region, the breakdown point is further pushed to a position, away from the transition region, in the cell region, to obtain a more optimized impact ionization distribution. As shown in the structure C in FIG. 5, based on the structure B1, the thickness of the second conduction type isolating body region of the transition region is reduced, and the position of the second conduction type transverse strip-shaped region is synchronously moved up; meanwhile, the longitudinal voltage-resistant lengths of the transition region and the terminal are increased and are greater than the longitudinal voltage-resistant length of the cell region; and compared with the impact ionization distribution of the structure B1 extending to the terminal region, the structure C has a more uniform impact ionization distribution concentrated in the cell region, and the stability of the device in the off state is improved.

### Embodiment 4

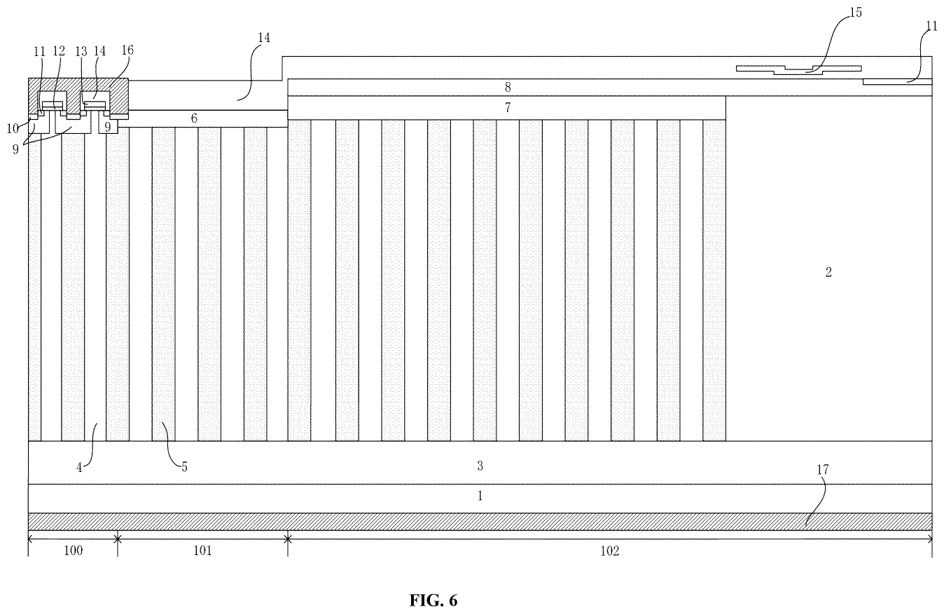

As shown in FIG. 6, the difference between this embodiment and Embodiment 1 is that: the lower boundary of the second conduction type isolating body region 6 in the transition region 101 is higher than the lower boundary of the second conduction type body region 9 in the cell region 100, and the lower boundary of the second conduction type transverse strip-shaped region 7 in the terminal region 102 is higher than the lower boundary of the isolating body region 6. In this embodiment, on the basis of thinning the isolating body region 6 of the transition region, the second conduction type transverse strip-shaped region 7 of the terminal region is further moved up to obtain a transverse segmented lifted structure and optimize the electristatic potential distribution of the device in terminal.

### Embodiment 5

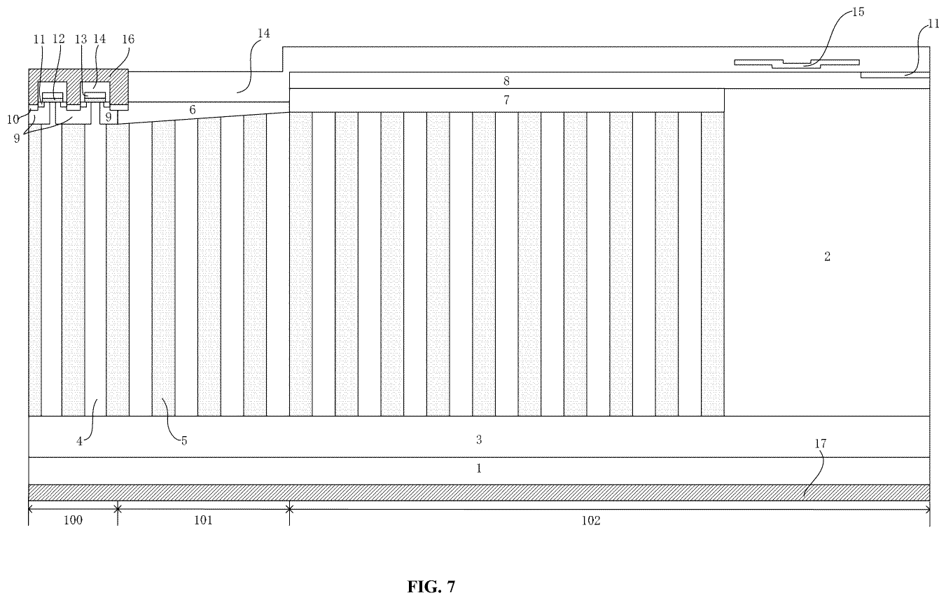

As shown in FIG. 7, the difference between this embodiment and Embodiment 1 is that: the lower boundary of the second conduction type isolating body region 6 in the transition region 101 is lifted from left to right to be in flush with the lower boundary of the second conduction type transverse strip-shaped region 7 in the terminal region 102, and the left lower boundary of the second conduction type isolating body region 6 is flush with the lower boundary of the second conduction type body region 9.

The principle of the structure in this embodiment is the same as that in Embodiment 3. The gradually-reduced thickness of the region 6 increases the voltage-resistant lengths of the transition region and the terminal region, and the slope structure of the region 6 provides a buffer strip between the cell region and the terminal region at the same time, thereby avoiding the sudden change of the electric field, providing a more uniform smoothly-changed electric field distribution and improving the stability of the device.

### Embodiment 6

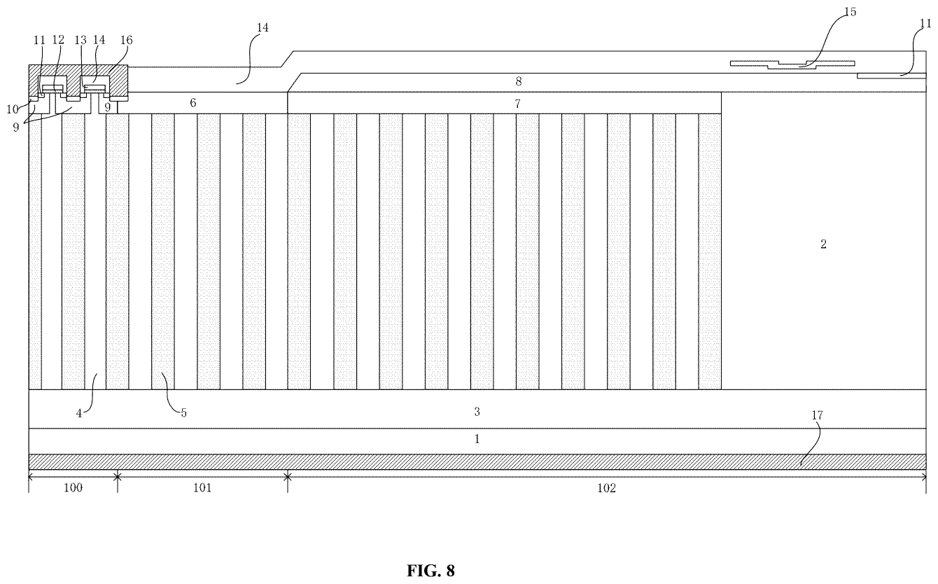

As shown in FIG. 8, the difference between this embodiment and Embodiment 1 is that: the steps of the first conduction type transverse strip-shaped region 8 and the dielectric layer 14 above the first conduction type transverse strip-shaped region at the junction of the transition region 101 and the terminal region 102 have a slope structure.

According to this embodiment, the defect of top step coverage is improved, so that the top dielectric layer and the metal are covered more uniformly, the reliability of the device can be improved, and the risk of failure can be reduced.

### Embodiment 7

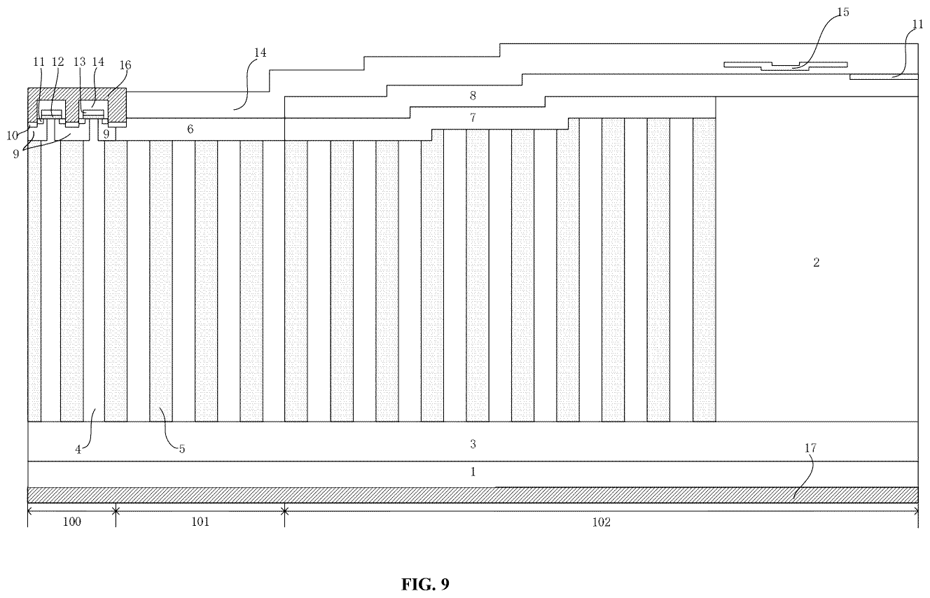

As shown in FIG. 9, the difference between this embodiment and Embodiment 1 is that: the first conduction type transverse strip-shaped region 8 and the second conduction type transverse strip-shaped region 7 in the terminal region 102 are lifted from left to right in a stepped shape and in a segmented manner.

According to this embodiment, by increasing the length of the longitudinal PN strip of the terminal in a segmented manner to further optimize the voltage resistance of the device, the electric field distribution of the terminal region is overally optimized, and the voltage resistance of the device is improved.

### Embodiment 8

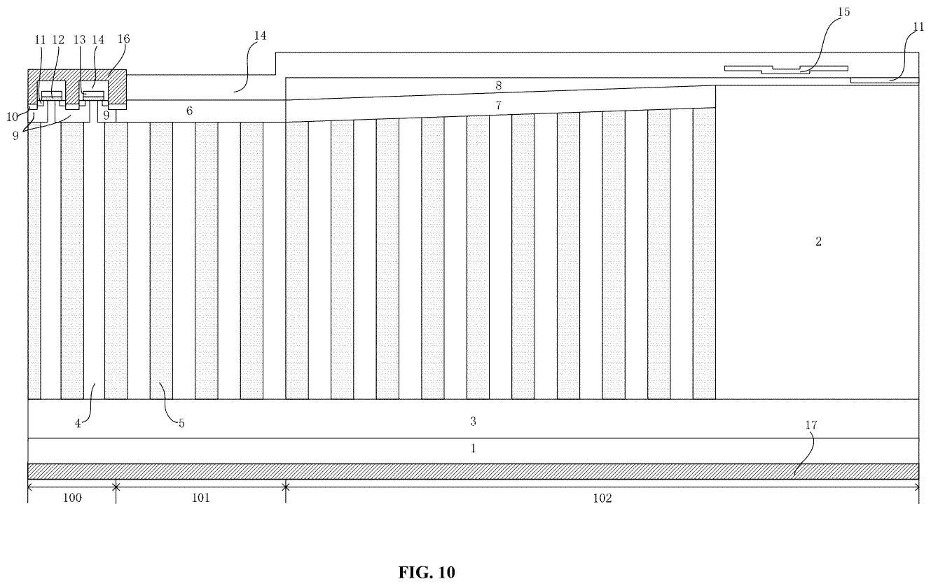

As shown in FIG. 10, the difference between this embodiment and Embodiment 1 is that: the upper and lower surfaces of the second conduction type transverse strip-shaped region 7 in the terminal region 102 are lifted from left to right in a slope shape from the right boundary of the second conduction type isolating body region 6, and the thickness of the second conduction type transverse strip-shaped region 7 is unchanged.

In this embodiment, the second conduction type region 7 is lifted in the slope shape, so that the longitudinal voltage-resistant length of the terminal region is increased smoothly; and by optimizing the concentrations of the second conduction type transverse strip-shaped region 7 and the first conduction type transverse strip-shaped region 8 at the top, the top depletion distribution and the terminal electric field distribution can be optimized while the breakdown position is transferred.

### Embodiment 9

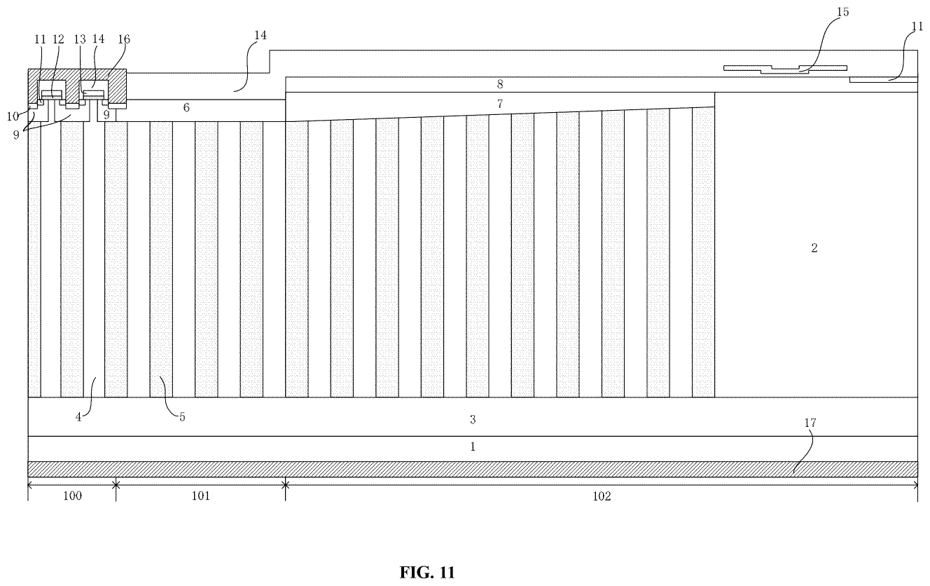

As shown in FIG. 11, the difference between this embodiment and Embodiment 1 is that: the lower surface of the second conduction type transverse strip-shaped region 7 in the terminal region 102 is lifted from left to right in a slope shape from the right boundary of the second conduction type isolating body region 6, and the upper surface of the second conduction type transverse strip-shaped region 7 is kept horizontal.

The objective of this embodiment is the same as that of Embodiment 8, and is to obtain the smooth and uniform electric field distribution at the top through the region 7 distributed in a slope shape and improve the reliability. In this embodiment, the transverse thickness of the second conduction type transverse strip-shaped region 7 is changed, and the concentrations of the second conduction type transverse strip-shaped region 7 and the first conduction type transverse strip-shaped region 8 are adjusted flexibly, thereby achieving the objective characteristics.

### Embodiment 10

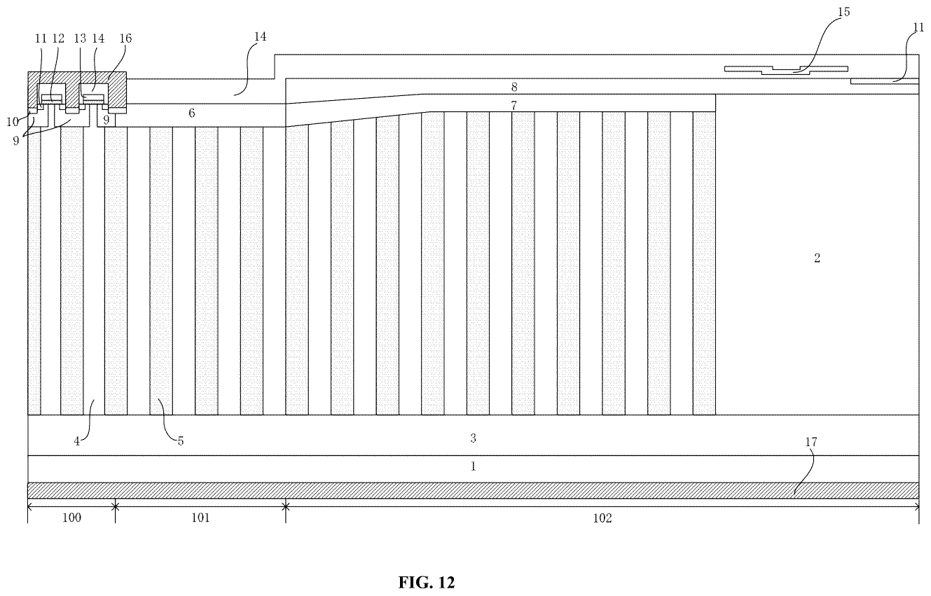

As shown in FIG. 12, the difference between this embodiment and Embodiment 1 is that: the second conduction type transverse strip-shaped region 7 in the terminal region 102 is divided into a left-side part and a right-side part with the same thickness, the left-side part is lifted in a slope shape from the right boundary of the second conduction type isolating body region 6, and the right-side part is kept horizontal. The lower boundary of the second conduction type transverse strip-shaped region 7 is connected to the upper surface of the second conduction type longitudinal strip-shaped region 5. The principle of this embodiment is the same as that of Embodiment 5, a voltage-resistant buffer region is formed by using a slope type second conduction type strip, and while the voltage resistance of the terminal is optimized, the concentration problem of the electric field is relieved, and the reliability of the device is improved.

### Embodiment 11

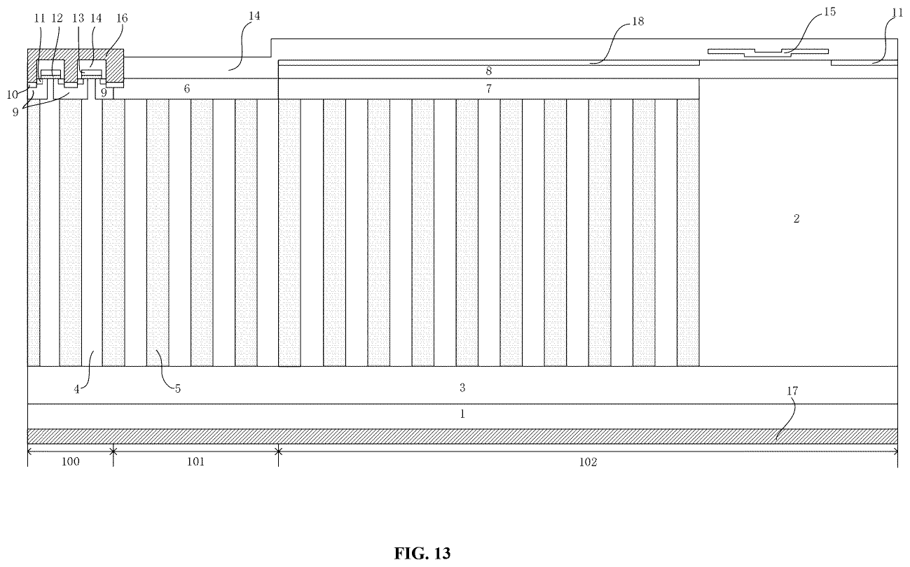

As shown in FIG. 13, the difference between this embodiment and embodiment 1 is that: a second conduction type thin layer region 18 is arranged at the top of the first conduction type transverse strip-shaped region 8, the voltage resistance of the top is optimized by a multiple resurf principle, and the more optimized depletion distribution and electric field distribution can be obtained by flexibly adjusting the top P/N doping.

### Embodiment 12

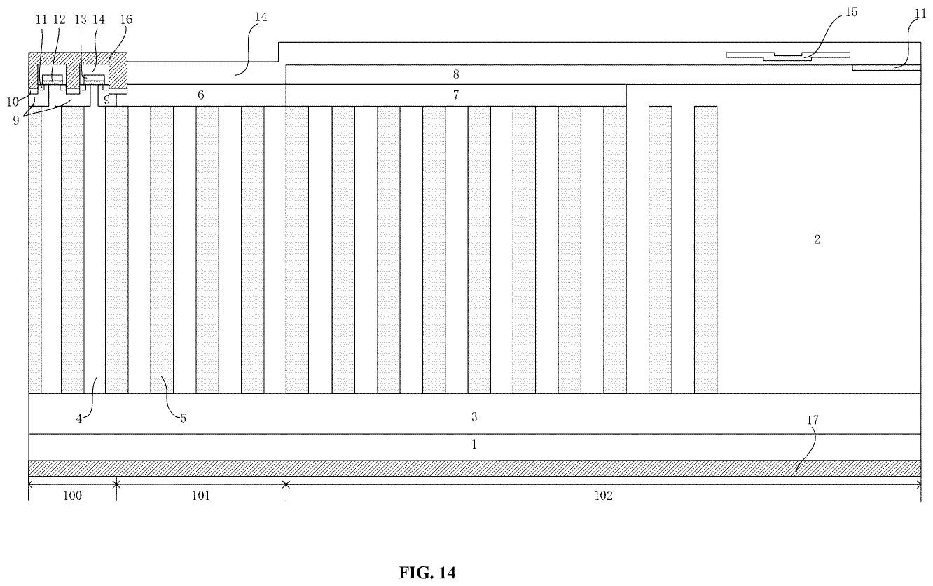

As shown in FIG. 14, the difference between this embodiment and Embodiment 1 is that: the length of the second conduction type transverse strip-shaped region 7 in the terminal region 102 and the number of the second conduction type longitudinal strip-shaped regions 5 are adjustable, and a plurality of the first conduction type longitudinal strip-shaped regions 4 and the second conduction type longitudinal strip-shaped regions 5 which are not connected to the second conduction type transverse strip-shaped region 7 are arranged below the right side of the second conduction type transverse strip-shaped region 7.

The second conduction type longitudinal strip-shaped regions 5 not connected to the transverse strip-shaped region 7 are floated. In this embodiment, the voltage-resistant length of the terminal can be flexibly adjusted according to the BV requirement of the device, and the number of floating strips is increased, so that the electric field and potential distribution of the device can be optimized based on that the BV of the device reaches the standard, and the more optimized off-state characteristic can be achieved.

### Embodiment 13

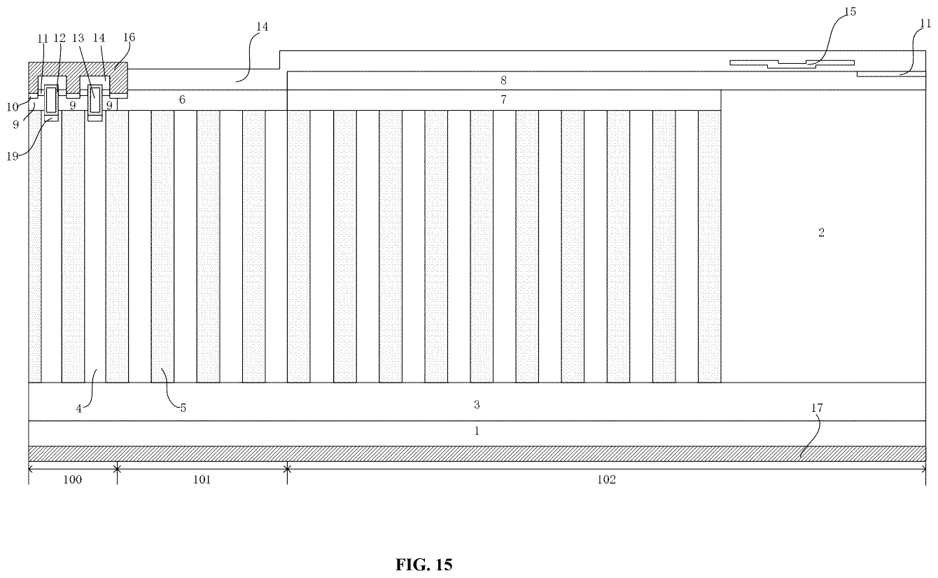

As shown in FIG. 15, the difference between this embodiment and Embodiment 1 is that: a planar gate in the cell region 100 is replaced by a trenchgate structure, and a second conduction type implantation region 19 is added at the bottom of the trenchgate. In the cell region 100, second conduction type body regions 9 are arranged at the top of the first conduction type epitaxial layer 3; and in the second conduction type body regions 9, trenches extending to the first conduction type longitudinal strip-shaped regions 4 below are formed, the trenches are filled with gateoxide layers 12 and gate electrode polysilicon 13, first conduction type heavy doping regions 11 are arranged on two sides of the trenches, the first conduction type heavy doping regions 11 and second conduction type body contact regions 10 are connected to a source electrode metal 16, and a second conduction type implantation region 19 is arranged in the first conduction type epitaxial layer 2 and located at the bottoms of the trenches.

In this embodiment, by adoption of the trenchgate structure, the size of the cell can be further reduced, the on resistance of the device can be reduced, the parasitic capacitance is smaller, the switching speed is high, the switching loss is low, and the current capability of the device can be improved; meanwhile, the second conduction type doping region is introduced at the bottom of the trenchgate, the dynamic characteristic of the device is further optimized on the basis of avoiding the preferential breakdown of the gateoxide layer.

### Embodiment 14

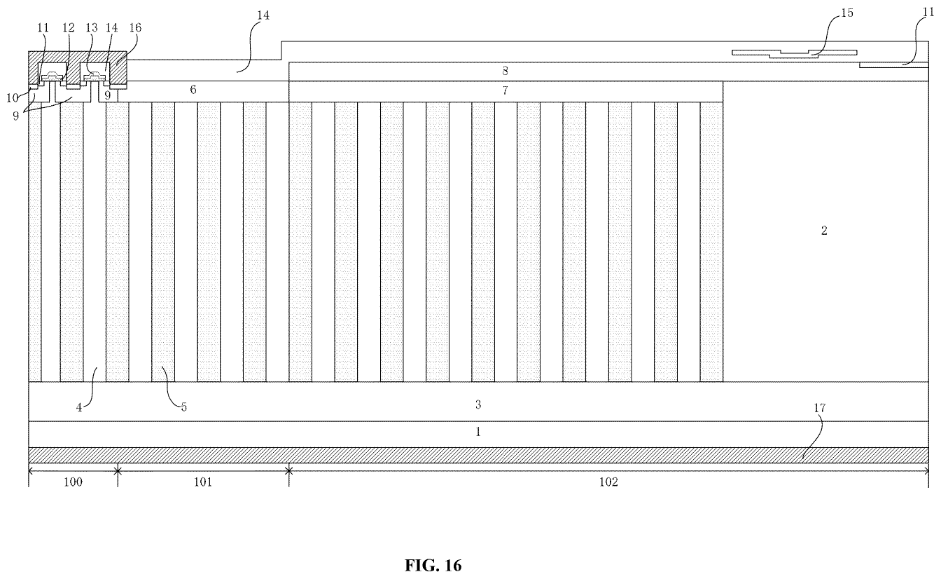

As shown in FIG. 16, the difference between this embodiment and Embodiment 1 is that: a stepped oxide layer with a thick middle and two thin sides is arranged above the second conduction type body region 9 in the cell region 100, and a thin-layer oxide layer with two sides located on a channel region is a gateoxide layer 12. The oxide layer below the polysilicon gate at the middle section is thicker, and the gateoxide layers on two sides are thinner. This embodiment adopts a special gate electrode structure, and in a case that the thicknesses of the gate oxide on two sides are sufficient to normally open the channel, the thickness of the middle gate oxide is increased to reduce the capacitance and the gate charge, thereby reducing the requirement of a gate driving circuit and the power consumption, and further optimizing the dynamic characteristic of the device.

The above embodiments are only intended to exemplarily illustrate the principle and effect of the present disclosure, but not intended to limit the present disclosure. Any person skilled in the art can modify or change the above embodiments without departing from the spirit and scope of the present disclosure. Therefore, all equivalent modifications or changes made by those with ordinary knowledge in the art without departing the spirit and technical ideal disclosed by the present disclosure should still be covered within the claims of the present disclosure.

What is claimed is:

1. A power semiconductor device, comprising a cell region, a transition region, and a terminal region,
wherein the transition region is located between the cell region and the terminal region of the device; the cell region, the transition region, and the terminal region of the device have a common bottom structure; the bottom structure comprises a drain electrode metal, a first conduction type substrate located above the drain electrode metal, a first conduction type epitaxial layer located above the first conduction type substrate, and a first conduction type buffer layer located at an inner bottom of the first conduction type epitaxial layer; a direction from the first conduction type epitaxial layer to the first conduction type substrate is defined as a device longitudinal direction, and a direction from the cell region to the terminal region is defined as a device transverse direction;
in the cell region, first conduction type longitudinal strip-shaped regions and second conduction type longitudinal strip-shaped regions which are distributed alternately in a transverse direction are arranged in the first conduction type epitaxial layer, second conduction type body regions are arranged at the tops of the first conduction type longitudinal strip-shaped regions and the second conduction type longitudinal strip-shaped regions, and first conduction type heavy doping regions and second conduction type body contact regions are arranged in the second conduction type body regions; the first conduction type heavy doping regions are located on left and right sides of the second conduction type body contact regions; the first conduction type heavy doping regions and the second conduction type body contact regions are connected to a source electrode metal; gateoxide layers are arranged above the second conduction type body regions; gate polysilicon is arranged above the gateoxide layers, and dielectric layers and the source electrode metal are arranged above the gate polysilicon;
in the transition region, first conduction type longitudinal strip-shaped regions and second conduction type longitudinal strip-shaped regions which are distributed alternately in the transverse direction are arranged in the first conduction type epitaxial layer, a second conduction type isolating body region is arranged at the tops of the first conduction type longitudinal strip-shaped regions and the second conduction type longitudinal strip-shaped regions, and the second conduction type longitudinal strip-shaped regions and the first conduction type longitudinal strip-shaped regions are connected to the second conduction type isolating body region; a dielectric layer is arranged above the second conduction type isolating body region;
the terminal region comprises first conduction type longitudinal strip-shaped regions and second conduction type longitudinal strip-shaped regions which are alternately distributed in the transverse direction, a second conduction type transverse strip-shaped region is arranged at the tops of the first conduction type longitudinal strip-shaped regions and the second conduction type longitudinal strip-shaped regions, a left-side boundary of the second conduction type transverse strip-shaped region is connected to the second conduction type isolating body region in the transition region, a lower boundary of the second conduction type transverse strip-shaped region is not lower than a lower boundary of the second conduction type isolating body region, and the lower boundary of the second conduction type isolating body region is not lower than lower boundaries of the second conduction type body regions; and
the lower boundary of the second conduction type transverse strip-shaped region is connected to a plurality of the first conduction type longitudinal strip-shaped regions and the second conduction type longitudinal strip-shaped regions; a first conduction type transverse strip-shaped region is arranged above the second conduction type transverse strip-shaped region, and an upper boundary of the first conduction type transverse strip-shaped region is higher than a silicon-oxide interface at the junction of the second conduction type isolating body region and the dielectric layer of the transition region to form a silicon layer step; and a dielectric layer is arranged above the first conduction type transverse strip-shaped region, a drain electrode polysilicon field plate is arranged in the dielectric layer and located at the rightmost end of the device, and a first conduction type heavy doping region is arranged below the drain electrode polysilicon field plate and is in short-circuit connection with the drain electrode polysilicon field plate.

2. The power semiconductor device according to claim 1, wherein the lower boundary of the second conduction type transverse strip-shaped region is flush with the lower boundary of the second conduction type isolating body region, and the lower boundary of the second conduction type isolating body region is flush with the lower boundaries of the second conduction type body regions.

3. The power semiconductor device according to claim 1, wherein the lower boundary of the second conduction type transverse strip-shaped region in the terminal region is higher than the lower boundary of the second conduction type isolating body region.

4. The power semiconductor device according to claim 1, wherein the lower boundary of the second conduction type isolating body region in the transition region is higher than the lower boundaries of the second conduction type body regions in the cell region, and the lower boundary of the second conduction type transverse strip-shaped region in the terminal region is flush with the lower boundary of the second conduction type isolating body region.

5. The power semiconductor device according to claim 1, wherein the lower boundary of the second conduction type isolating body region in the transition region is higher than the lower boundaries of the second conduction type body regions in the cell region, and the lower boundary of the second conduction type transverse strip-shaped region in the terminal region is higher than the lower boundary of the isolating body region.

6. The power semiconductor device according to claim 1, wherein the lower boundary of the second conduction type isolating body region in the transition region is lifted from left to right to be flush with the lower boundary of the second conduction type transverse strip-shaped region in the terminal region, and a lower left boundary of the second conduction type isolating body region is flush with the lower boundaries of the second conduction type body regions.

7. The power semiconductor device according to claim 1, wherein a step of the first conduction type transverse strip-shaped region and the dielectric layer above at the junction of the transition region and the terminal region is of a right-angle or slope structure.

8. The power semiconductor device according to claim 1, wherein the first conduction type transverse strip-shaped region and the second conduction type transverse strip-shaped region in the terminal region are lifted from left to right in a stepped shape and in a segmented manner.

9. The power semiconductor device according to claim 1, wherein an upper surface and a lower surface of the second conduction type transverse strip-shaped region in the terminal region are lifted from left to right in a slope shape from a right boundary of the second conduction type isolating body region, and a thickness of the second conduction type transverse strip-shaped region is unchanged.

10. The power semiconductor device according to claim 1, wherein a lower surface of the second conduction type transverse strip-shaped region in the terminal region is lifted from left to right in a slope shape from a right boundary of the second conduction type isolating body region, and an upper surface of the second conduction type transverse strip-shaped region is kept horizontal.

11. The power semiconductor device according to claim 1, wherein the second conduction type transverse strip-shaped region in the terminal region is divided into a left-side part and a right-side part with the same thickness, the left-side part is lifted in a slope shape from a right boundary of the second conduction type isolating body region, and the right-side part is kept horizontal.

12. The power semiconductor device according to claim 1, wherein a second conduction type thin layer region is arranged at the top of the first conduction type transverse strip-shaped region.

13. The power semiconductor device according to claim 1, wherein a plurality of the first conduction type longitudinal strip-shaped regions and the second conduction type longitudinal strip-shaped regions which are not connected to the second conduction type transverse strip-shaped region are arranged below the right side of the second conduction type transverse strip-shaped region.

14. The power semiconductor device according to claim 1, wherein in the cell region, a gate electrode structure is a trenchgate structure, and the second conduction type body regions are arranged at the top of the first conduction type epitaxial layer; and in the second conduction type body regions, trenches extending to the first conduction type longitudinal strip-shaped regions below are formed, the trenches are filled with the gateoxide layers and the gate electrode polysilicon, the first conduction type heavy doping regions are arranged on two sides of the trenches, the first conduction type heavy doping regions and the second conduction type body contact regions are connected to the source electrode metal, and a second conduction type implantation region is arranged in the first conduction type epitaxial layer and located at the bottoms of the trenches.

15. The power semiconductor device according to claim 1, wherein in the cell region, a stepped oxide layer with a thick middle part and two thin sides is arranged above the second conduction type body regions, and thin oxide layers above channel regions on two sides are the gateoxide layers.

16. The power semiconductor device according to claim 1, wherein in the cell region, each of the first conduction type longitudinal strip-shaped regions has a concentration the same as or different from that of the first conduction type epitaxial layer, and/or a first conduction type JFET implantation region is arranged at the top of each of the first conduction type longitudinal strip-shaped regions.

17. The power semiconductor device according to claim 1, wherein in the transition region, a first conduction type heavy doping region is added in the second conduction type isolating body region to serve as a channel structure.

18. The power semiconductor device according to claim 1, wherein the first conduction type longitudinal strip-shaped regions, the second conduction type longitudinal strip-shaped regions, the first conduction type transverse strip-shaped region, the second conduction type isolating body region and the second conduction type transverse strip-shaped region are obtained by a method of multi-epitaxy and ion implantation;
or/and the silicon layer step between the transition region and the terminal region is obtained through a process of etching after epitaxy or local epitaxy.

19. The power semiconductor device according to claim 1, wherein the structure comprises an N-type power semiconductor device and a terminal structure thereof, and a P-type power semiconductor device and a terminal structure thereof; for the terminal structure of the N-type power semiconductor device, the first conduction type is an N type, and the second conduction type is a P type; and for the terminal structure of the P-type semiconductor device, the first conduction type is the P type, and the second conduction type is the N type.
